(19) United States
(12) Patent Application Publication
(10) Pub. No.: US 2025/0109242 A1
(43) Pub. Date: Apr. 3, 2025

(54) COMPOSITION FOR FORMING RESIST UNDERLAYER FILM CONTAINING HYDROXYCINNAMIC ACID DERIVATIVE

(71) Applicant: NISSAN CHEMICAL CORPORATION, Tokyo (JP)

(72) Inventors: Shun KUBODERA, Toyama-shi (JP); Tokio NISHITA, Toyama-shi (JP); Takahiro KISHIOKA, Toyama-shi (JP); Gun SON, Toyama-shi (JP)

(73) Assignee: NISSAN CHEMICAL CORPORATION, Tokyo (JP)

(21) Appl. No.: 18/714,012

(22) PCT Filed: Oct. 17, 2022
(86) PCT No.: PCT/JP2022/038574

§ 371 Date: May 28, 2024

(30) Foreign Application Priority Data
Nov. 30, 2021 (JP) 2021-193850

(51) Int. Cl. C08G 59/62; C08K 5/3492; G03F 7/11; H01L 21/027; H01L 21/48

(52) U.S. Cl. CPC C08G 59/628; C08K 5/34922; G03F 7/11; H01L 21/0275; H01L 21/0276; H01L 21/4846

(57) ABSTRACT

A resist underlayer film exhibits excellent removability in a wet etching chemical liquid while mainly exhibiting excellent resistance to a resist solvent or a resist developer. A composition for forming a resist underlayer film for i-line contains a reaction product of a bifunctional or higher glycidyl ester type epoxy resin and a compound A represented by the following Formula (A), and a solvent.

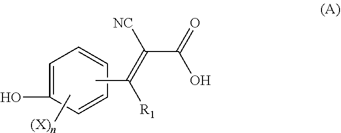

(In Formula (A), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, and n represents an integer from 0 to 4.)

### TECHNICAL FIELD

The present invention relates to a composition for forming a resist underlayer film, a resist underlayer film obtained using the composition for forming a resist underlayer film, a method for manufacturing a patterned substrate and a method for manufacturing a semiconductor device using the composition for forming a resist underlayer film, and a hydroxycinnamic acid derivative compound.

### BACKGROUND ART

In manufacturing a semiconductor, a lithography process for forming a resist pattern having a desired shape by providing a resist underlayer film between a substrate and a resist film formed thereon is widely known. After the resist pattern is formed, the resist underlayer film is removed and the substrate is processed, and dry etching is mainly used as the process. Patent Literature 1 discloses an anti-reflective coating composition for obtaining a desired resist pattern by applying a resist onto a resist underlayer film and performing exposure and development using radiation (for example, ArF excimer laser light, KrF excimer laser light, or i-line). On the other hand, in the three-dimensional mounting field of semiconductor manufacturing processes, a FOWLP process has started to be applied for the purpose of high-speed responsiveness and power saving by shortening a wiring length between semiconductor chips, and a lithography process using i-line is used in a redistribution layer (RDL) process of creating a wiring between semiconductor chips, but simplification of the process is strongly desired in order to reduce the process cost. In general, dry etching is also used in a process of removing an unnecessary resist pattern or a base resist underlayer film after substrate processing, but wet etching using a chemical liquid may be used particularly in the RDL process for the purpose of simplifying the process or reducing damage to the processed substrate.

### CITATION LIST

### Patent Literature

Patent Literature 1: WO 2009/008446 A

### SUMMARY OF INVENTION

### Technical Problem

As described above, in the FOWLP process which is one of the three-dimensional mounting techniques of the semiconductor manufacturing process, there is a redistribution layer (RDL) process using i-line lithography. In particular, in a so-called post-process such as the RDL process, in order to reduce the process cost, the resist underlayer film is strongly required to have wet etching removability in a chemical liquid. When the resist underlayer film is removed by wet etching with a chemical liquid, the resist underlayer film is required to have sufficient solubility in a wet etching chemical liquid and to be easily removed from the substrate.

On the other hand, as a wet etching chemical liquid for removing the resist and the resist underlayer film, an organic solvent is used in order to reduce damage to the processed substrate. Furthermore, in order to improve removability of the resist and the resist underlayer film, a basic organic solvent is used. However, the resist underlayer film has limitations in the prior art in that it exhibits removability, and preferably solubility, only in a wet etching chemical liquid, while mainly exhibiting excellent resistance to a resist solvent, which is an organic solvent, or a resist developer, which is an alkaline aqueous solution. An object of the present invention is to solve the above problems.

### Solution to Problem

As a result of intensive studies to solve the above problems, the present inventors have found that a film obtained using a composition for forming a resist underlayer film containing a reaction product obtained by reacting a bifunctional or higher glycidyl ester type epoxy resin with a hydroxycinnamic acid derivative compound represented by a specific structural formula exhibits excellent resistance to a resist solvent or a resist developer which is an alkaline aqueous solution, and exhibits excellent removability (solubility) in a wet etching chemical liquid while having an excellent k value at i-line, thereby completing the present invention.

That is, the present invention encompasses the following aspects.

[1] A composition for forming a resist underlayer film for i-line, the composition containing:
a reaction product of a bifunctional or higher glycidyl ester type epoxy resin and a compound A represented by the following Formula (A); and
a solvent.

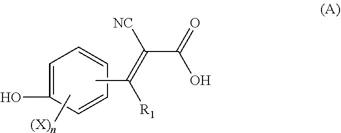

(In Formula (A), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, and n represents an integer from 0 to 4.)

[2] A composition for forming a resist underlayer film for i-line, the composition containing a compound having a structure represented by the following Formula (1) or a compound having a structure represented by the following Formula (2), and a solvent.

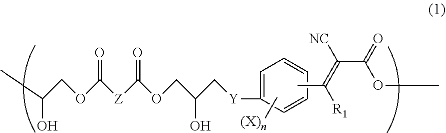

(In Formula (1), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, Z represents an alkylene group having 1 to 6 carbon atoms, a divalent organic group containing a ring selected from the group consisting of an aromatic ring which may have a substituent, an aliphatic ring which may have a substituent, and a heterocyclic ring which may have a substituent, or a divalent organic group containing the ring and an alkylene group having 1 to 6 carbon atoms, and n represents an integer from 0 to 4.)

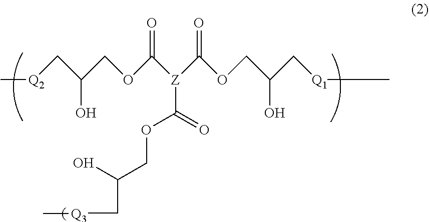

(In Formula (2), Z represents a trivalent organic group containing a ring selected from the group consisting of an aromatic ring which may have a substituent, an aliphatic ring which may have a substituent, and a heterocyclic ring which may have a substituent, or a trivalent organic group containing the ring and an alkylene group having 1 to 6 carbon atoms, and Q₁, Q₂, and Q₃ each independently represent a divalent organic group having a structure represented by the following Formula (3).)

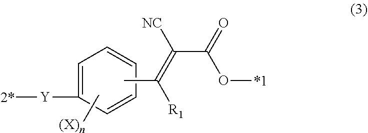

(In Formula (3), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, n represents an integer from 0 to 4, and *1 and *2 each represent a bond.)

[3] The composition for forming a resist underlayer film for i-line according to [1] or [2], further containing at least one selected from the group consisting of a crosslinking agent, an acid, and an acid generator.

[4] The composition for forming a resist underlayer film for i-line according to any one of [1] to [3], in which the composition is applied onto a substrate containing copper on a surface thereof.

[5] A resist underlayer film obtained by removing a solvent from a coating film made of the composition for forming a resist underlayer film for i-line according to any one of [1] to [3].

[6] A resist underlayer film obtained from the composition for forming a resist underlayer film for i-line according to any one of [1] to [3] that is dried or concentrated.

[7] The resist underlayer film according to [5] or [6], in which the resist underlayer film is formed on a substrate containing copper on a surface thereof.

[8] A substrate including a copper seed layer, and the resist underlayer film according to [5] or [6] formed on the copper seed layer, the copper seed layer and the resist underlayer film being formed on a surface of the substrate.

[9] A method for manufacturing a substrate including a patterned resist film, the method including:
a step of forming a resist underlayer film by applying the composition for forming a resist underlayer film for i-line according to any one of [1] to [3] onto a substrate containing copper on a surface thereof and baking the composition;
a step of forming a resist film by applying a resist onto the resist underlayer film and baking the resist;
a step of exposing the resist underlayer film and a semiconductor substrate coated with the resist; and
a step of developing the resist film after the exposure and performing patterning.

[10] A method for manufacturing a semiconductor device, the method including:
a step of forming a resist underlayer film from the composition for forming a resist underlayer film for i-line according to any one of [1] to [3] on a substrate containing copper on a surface thereof;
a step of forming a resist film on the resist underlayer film;
a step of forming a resist pattern by irradiating the resist film with light or an electron beam and subsequent development, and then removing the resist underlayer film exposed between the resist patterns;
a step of performing copper plating between the formed resist patterns; and
a step of removing the resist pattern and the resist underlayer film existing under the resist pattern.

[11] The method for manufacturing a semiconductor device according to [10], in which at least one of the steps of removing the resist underlayer film is performed by wet processing.

[12] A compound (1) having a structure represented by the following Formula (1):

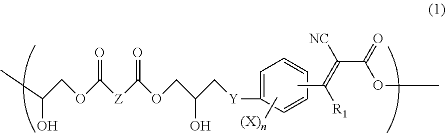

(in Formula (1), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, Z represents an alkylene group having 1 to 6 carbon atoms, a divalent organic group containing a ring selected from the group consisting of an aromatic ring which may have a substituent, an aliphatic ring which may have a substituent, and a heterocyclic ring which may have a substituent, or a divalent organic group containing the ring and an alkylene group having 1 to 6 carbon atoms, and n represents an integer from 0 to 4).

[13] A compound (2) having a structure represented by the following Formula (2):

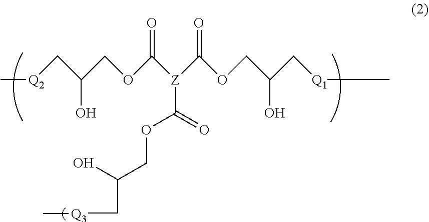

(in Formula (2), Z represents a trivalent organic group containing a ring selected from the group consisting of an aromatic ring which may have a substituent, an aliphatic ring which may have a substituent, and a heterocyclic ring which may have a substituent, or a trivalent organic group containing the ring and an alkylene group having 1 to 6 carbon atoms, and Q₁, Q₂, and Q₃ each independently represent a divalent organic group having a structure represented by the following Formula (3)),

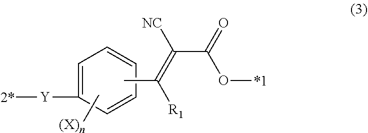

(in Formula (3), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, n represents an integer from 0 to 4, and *1 and *2 each represent a bond).

### Advantageous Effects of Invention

According to the present invention, it is possible to provide a resist underlayer film that exhibits excellent removability (solubility) in a wet etching chemical liquid while mainly exhibiting excellent resistance to a resist solvent, which is an organic solvent, or a resist developer, which is an alkaline aqueous solution.

### DESCRIPTION OF EMBODIMENTS

Hereinafter, the present invention will be described in detail. Note that the description of the constituent elements described below is an example for describing the present invention, and the present invention is not limited to these contents.

### (Composition for Forming Resist Underlayer Film)

A composition for forming a resist underlayer film for i-line of the present invention (hereinafter, also referred to as a composition for forming a resist underlayer film) contains a reaction product obtained by reacting a bifunctional or higher glycidyl ester type epoxy resin with a hydroxycinnamic acid derivative compound represented by a specific structural formula (hereinafter, also referred to as a reaction product having a specific structure), and a solvent.

The composition for forming a resist underlayer film of the present invention can further contain at least one selected from the group consisting of a crosslinking agent, an acid, and an acid generator, and other components, in addition to the reaction product having a specific structure and the solvent.

### <Reaction Product Having Specific Structure>

The reaction product having a specific structure according to the present invention is obtained by reacting a bifunctional or higher glycidyl ester type epoxy resin with a compound A represented by the following Formula (A).

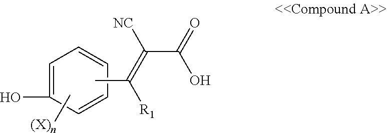

(In Formula (A), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, and n represents an integer from 0 to 4.)

Examples of the alkyl group having 1 to 10 carbon atoms include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, and a decyl group.

Examples of the aryl group having 6 to 40 carbon atoms include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-fluorophenyl group, an o-methoxyphenyl group, a p-methoxyphenyl group, a p-nitrophenyl group, a p-cyanophenyl group, an α-naphthyl group, a β-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the alkoxy group having 1 to 10 carbon atoms include a group in which an oxygen atom is bonded to the alkyl group. Examples thereof include a methoxy group, an ethoxy group, an n-propoxy group, an i-propoxy group, an n-butoxy group, an i-butoxy group, an s-butoxy group, a t-butoxy group, an n-pentoxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, a 1-ethyl-2-methyl-n-propoxy group, an n-heptyloxy group, an n-octyloxy group, an n-nonyloxy group, and an n-decanoyloxy group.

Examples of the alkoxycarbonyl group having 1 to 10 carbon atoms include a group in which an oxygen atom and a carbonyl group are bonded to the alkyl group. Examples thereof include a methoxycarbonyl group, an ethoxycarbonyl group, a propoxycarbonyl group, and a butoxycarbonyl group.

Examples of the halogen atom include a fluorine atom, a chlorine atom, a bromine atom, and an iodine atom.

Specific examples of the hydroxycinnamic acid derivative compound represented by a specific structural formula as represented by Formula (A) include the following compounds.

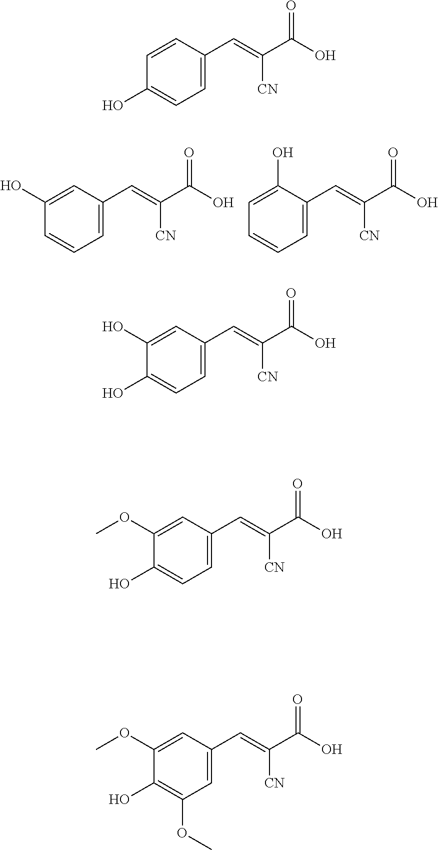

### <<Bifunctional or Higher Glycidyl Ester Type Epoxy Resin>>

In the present invention, a bifunctional or higher glycidyl ester type epoxy resin and a compound A represented by Formula (A) are reacted.

Here, the bifunctional or higher glycidyl ester type epoxy resin is a glycidyl ester type epoxy resin, contains two or more epoxy groups, and contains two or more ester groups.

By reacting a bifunctional or higher glycidyl ester type epoxy resin with the compound A represented by Formula (A), a polymer (reaction product) having, as a repeating unit, a unit obtained by reacting the bifunctional or higher glycidyl ester type epoxy resin with the compound A is obtained, and the repeating unit contains at least three or more ester groups. That is, two or more ester groups derived from the bifunctional or higher glycidyl ester type epoxy resin and one or more ester groups derived from the compound A are contained.

In the present invention, a polymer (reaction product) containing three or more ester groups is used per unit of repeating units constituting the polymer (reaction product), the polymer (reaction product) is contained in the composition for forming a resist underlayer film, and a resist underlayer film is formed using the composition for forming a resist underlayer film. As described above, it is presumed that the excellent effect of the present invention is obtained by using a reaction product in which three or more ester groups are present per repeating unit (one unit) as the reaction product to be contained in the composition for forming a resist underlayer film. That is, it is considered that the presence of three or more ester groups per repeating unit (one unit) increases the hydrolyzability, and therefore, excellent removability (solubility) in a wet etching chemical liquid when a resist underlayer film is formed is exhibited.

Examples of a preferred embodiment of the bifunctional or higher glycidyl ester type epoxy resin include a bifunctional glycidyl ester type epoxy resin represented by the following Formula (B1) and a trifunctional glycidyl ester type epoxy resin represented by the following Formula (B2).

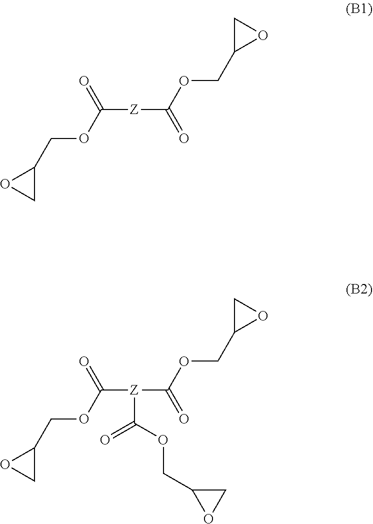

In Formula (B1), Z represents
(i) an alkylene group having 1 to 6 carbon atoms,
(ii) a divalent organic group containing a ring selected from the group consisting of an aromatic ring which may have a substituent, an aliphatic ring which may have a substituent, and a heterocyclic ring which may have a substituent, or
(iii) a divalent organic group containing the ring and an alkylene group having 1 to 6 carbon atoms.

In addition, in Formula (B2), Z represents
(iv) a trivalent organic group containing a ring selected from the group consisting of an aromatic ring which may have a substituent, an aliphatic ring which may have a substituent, and a heterocyclic ring which may have a substituent, or
(v) a trivalent organic group containing the ring and an alkylene group having 1 to 6 carbon atoms.

In (B1) and (B2), the alkylene group refers to a divalent group derived by further removing one hydrogen atom from the alkyl group. The alkylene group may be linear or branched.

In (B1) and (B2), specific examples of the aromatic ring include benzene, naphthalene, anthracene, acenaphthene, fluorene, triphenylene, phenalene, phenanthrene, indene, indane, indacene, pyrene, chrysene, perylene, naphthacene, pentacene, coronene, heptacene, benzo[a]anthracene, dibenzophenanthrene, and dibenzo[a,j]anthracene.

In (B1) and (B2), specific examples of the heterocyclic ring include furan, thiophene, pyrrole, imidazole, pyran, pyridine, pyrimidine, pyrazine, pyrrolidine, piperidine, piperazine, morpholine, quinuclidine, indole, purine, thymine, quinoline, isoquinoline, chromene, thianthrene, phenothiazine, phenoxazine, xanthene, acridine, phenazine, carbazole, hydantoin, uracil, barbiturate, triazine, and cyanuric acid. The heterocyclic ring may be triazinetrione, dioxoimidazoline, or diazinetrione.

In (B1) and (B2), the substituent in the aromatic ring which may have a substituent, the aliphatic ring which may have a substituent, or the heterocyclic ring which may have a substituent represents an alkyl group having 1 to 10 carbon atoms which may be interrupted by an oxygen atom or a sulfur atom, an alkenyl group having 2 to 10 carbon atoms which may be interrupted by an oxygen atom or a sulfur atom, or an alkynyl group having 2 to 10 carbon atoms which may be interrupted by an oxygen atom or a sulfur atom. The alkyl group, the alkenyl group, and the alkynyl group may be linear or branched.

The phrase “which may be interrupted” means that any carbon-carbon atom in the alkyl group, alkenyl group, or alkynyl group is interrupted by a heteroatom (that is, an ether bond in the case of oxygen, and a sulfide bond in the case of sulfur).

Specific examples of the bifunctional or higher glycidyl ester type epoxy resin include compounds represented by the following.

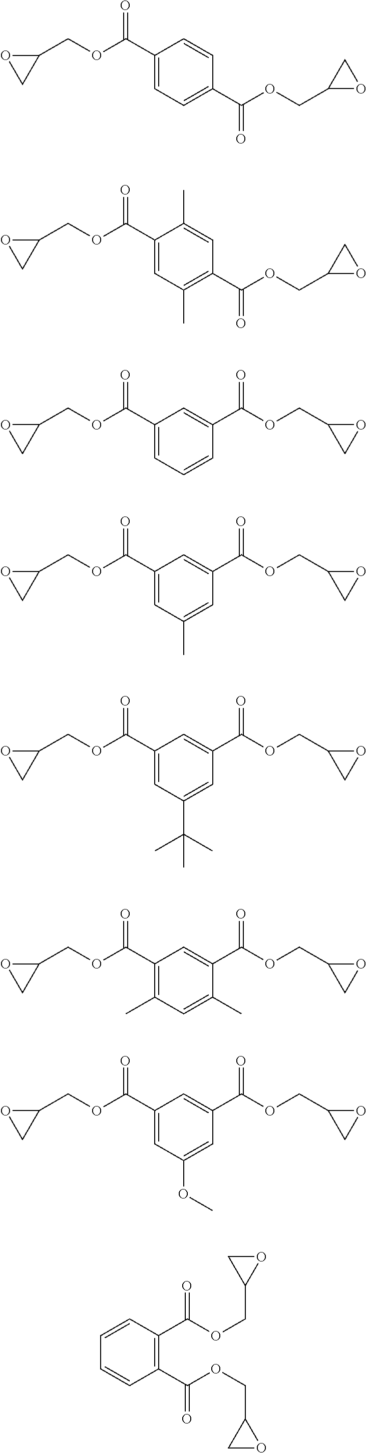

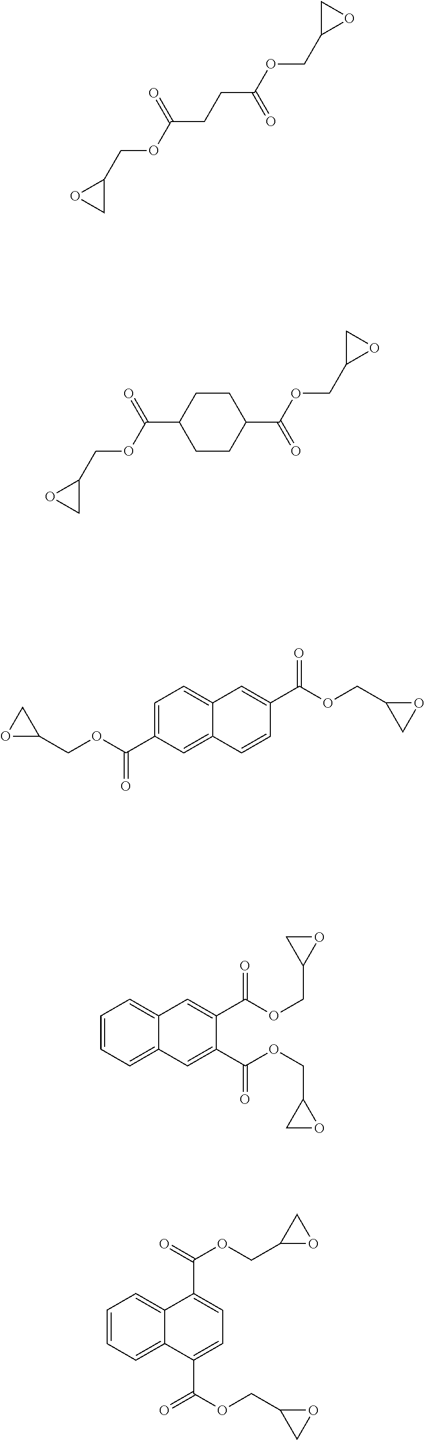 [SMILES: O=C(CCC(=O)OCC1CO1)OCC1CO1 ; O=C(OCC1CO1)C1CCC(C(=O)OCC2CO2)CC1 ; O=C(OCC1CO1)c1ccc2cc(C(=O)OCC3CO3)ccc2c1 ; O=C(OCC1CO1)c1cc2ccccc2cc1C(=O)OCC1CO1 ; O=C(OCC1CO1)c1ccc(C(=O)OCC2CO2)c2ccccc12]

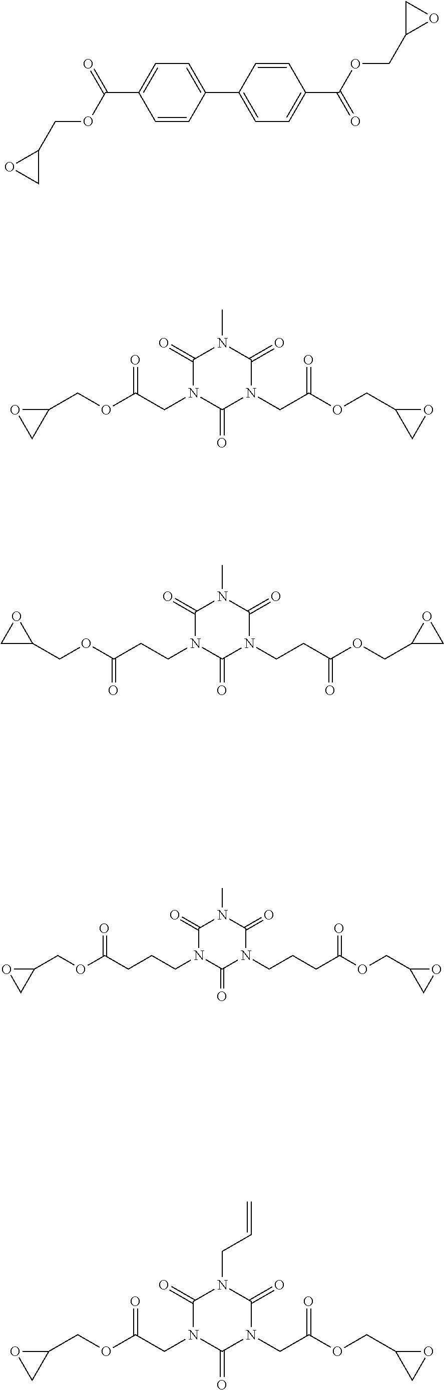 [SMILES: O=C(OCC1CO1)c1ccc(-c2ccc(C(=O)OCC3CO3)cc2)cc1 ; Cn1c(=O)n(CC(=O)OCC2CO2)c(=O)n(CC(=O)OCC2CO2)c1=O ; Cn1c(=O)n(CCC(=O)OCC2CO2)c(=O)n(CCC(=O)OCC2CO2)c1=O ; Cn1c(=O)n(CCCC(=O)OCC2CO2)c(=O)n(CCCC(=O)OCC2CO2)c1=O ; C=CCn1c(=O)n(CC(=O)OCC2CO2)c(=O)n(CC(=O)OCC2CO2)c1=O]

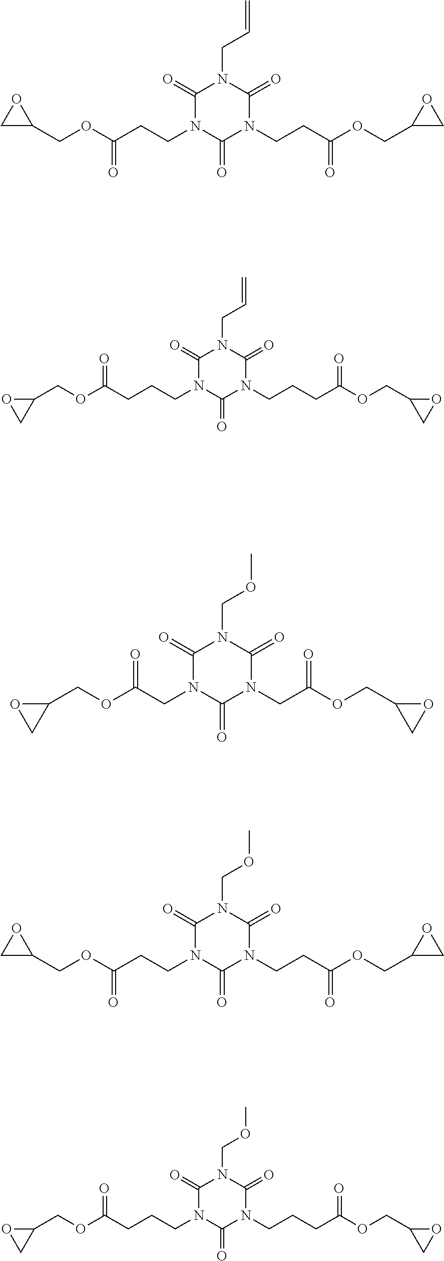 [SMILES: C=CCn1c(=O)n(CCC(=O)OCC2CO2)c(=O)n(CCC(=O)OCC2CO2)c1=O ; C=CCn1c(=O)n(CCCC(=O)OCC2CO2)c(=O)n(CCCC(=O)OCC2CO2)c1=O ; COCn1c(=O)n(CC(=O)OCC2CO2)c(=O)n(CC(=O)OCC2CO2)c1=O ; COCn1c(=O)n(CCC(=O)OCC2CO2)c(=O)n(CCC(=O)OCC2CO2)c1=O ; COCn1c(=O)n(CCCC(=O)OCC2CO2)c(=O)n(CCCC(=O)OCC2CO2)c1=O]

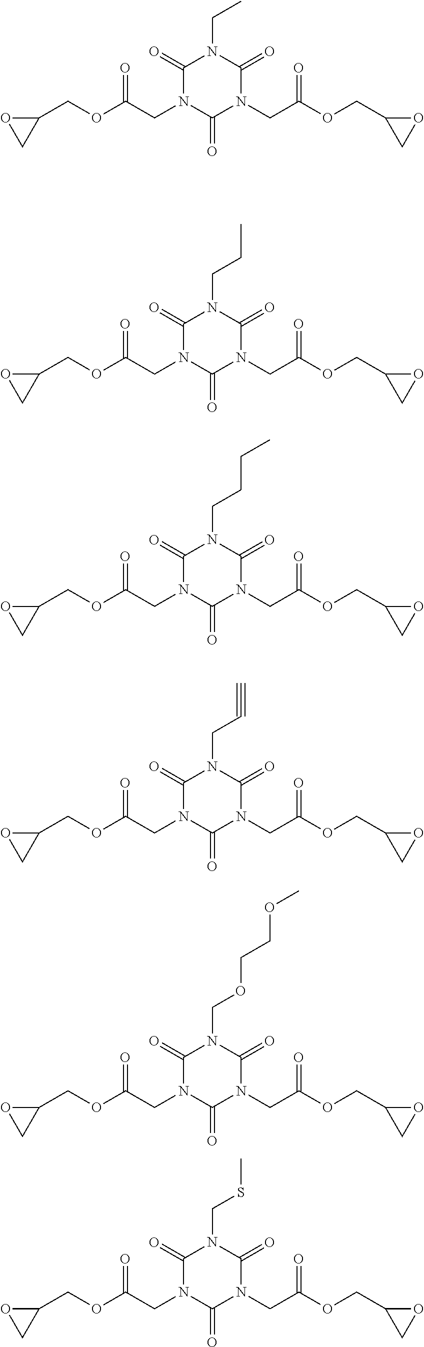

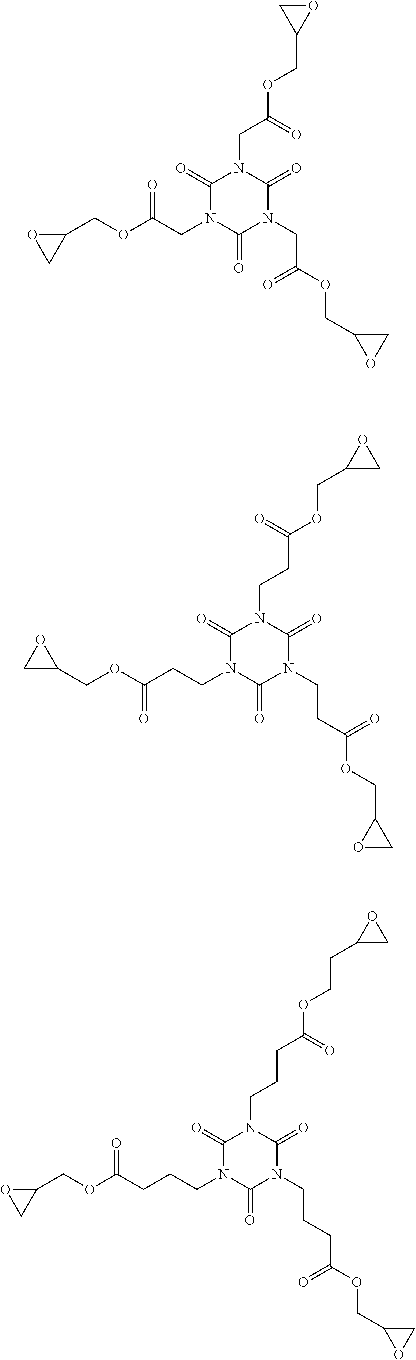 [SMILES: O=C(Cn1c(=O)n(CC(=O)OCC2CO2)c(=O)n(CC(=O)OCC2CO2)c1=O)OCC1CO1 ; O=C(CCn1c(=O)n(CCC(=O)OCC2CO2)c(=O)n(CCC(=O)OCC2CO2)c1=O)OCC1CO1 ; O=C(CCCn1c(=O)n(CCCC(=O)OCC2CO2)c(=O)n(CCCC(=O)OCC2CO2)c1=O)OCCC1CO1]

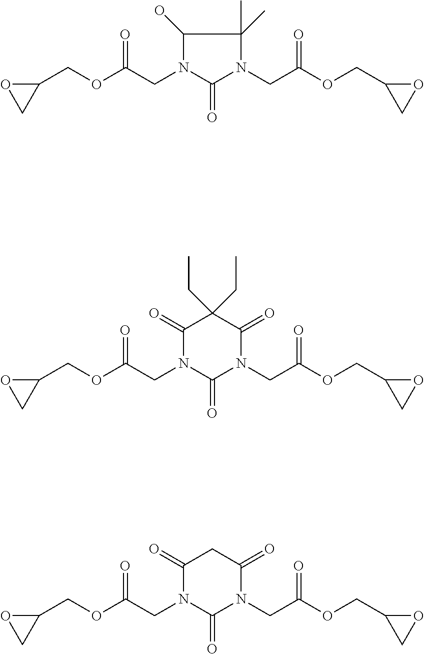 [SMILES: CC1(C)C(O)N(CC(=O)OCC2CO2)C(=O)N1CC(=O)OCC1CO1 ; CCC1(CC)C(=O)N(CC(=O)OCC2CO2)C(=O)N(CC(=O)OCC2CO2)C1=O ; O=C(CN1C(=O)CC(=O)N(CC(=O)OCC2CO2)C1=O)OCC1CO1]

Examples of a preferred embodiment of the reaction product having a specific structure include a compound having a structure represented by the following Formula (1) and a compound having a structure represented by the following Formula (2).

When the compound having a structure represented by the following Formula (1) or the compound having a structure represented by the following Formula (2) is contained in the composition for forming a resist underlayer film, the resist underlayer film formed using the composition for forming a resist underlayer film can exhibit not only excellent resistance to a resist solvent or a resist developer which is an alkaline aqueous solution but also excellent removability (solubility) in a wet etching chemical liquid.

### <<Compound Having Structure Represented by Formula (1)>>

The composition for forming a resist underlayer film of the present invention contains a compound having a structure represented by the following Formula (1) and a solvent.

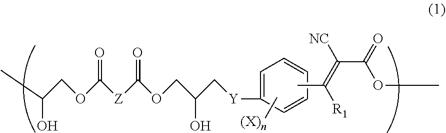

In Formula (1), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, Z represents an alkylene group having 1 to 6 carbon atoms, a divalent organic group containing a ring selected from the group consisting of an aromatic ring which may have a substituent, an aliphatic ring which may have a substituent, and a heterocyclic ring which may have a substituent, or a divalent organic group containing the ring and an alkylene group having 1 to 6 carbon atoms, and n represents an integer from 0 to 4.

The descriptions of R₁ and X in Formula (1) are as described in the section of <<Compound A>>.

The description of Z in Formula (1) is the same as the description of Z described in the description of Formula (B1) in the section of <<Bifunctional or higher glycidyl ester type epoxy resin>>.

### <<Compound Having Structure Represented by Formula (2)>>

The composition for forming a resist underlayer film of the present invention contains a compound having a structure represented by the following Formula (2) and a solvent.

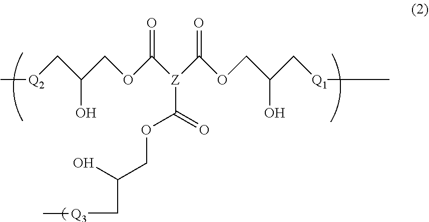

In Formula (2), Z represents a trivalent organic group containing a ring selected from the group consisting of an aromatic ring which may have a substituent, an aliphatic ring which may have a substituent, and a heterocyclic ring which may have a substituent, or a trivalent organic group containing the ring and an alkylene group having 1 to 6 carbon atoms, and Q₁, Q₂, and Q₃ each independently represent a divalent organic group having a structure represented by the following Formula (3).

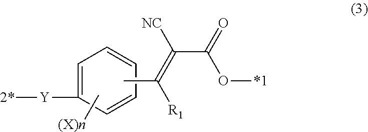

In Formula (3), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, n represents an integer from 0 to 4, and *1 and *2 each represent a bond.

Q₁, Q₂, and Q₃ in Formula (2) may be independently any of *1 and *2 in Formula (3) as a bond bonded to a structural side including Z in Formula (2).

The descriptions of R₁ and X in Formulas (2) and (3) are as described in the section of <<Compound A>>.

The description of Z in Formula (2) is the same as the description of Z described in the description of Formula (B2) in the section of <<Bifunctional or higher glycidyl ester type epoxy resin>>.

For example, when each of Q₁, Q₂, and Q₃ in Formula (2) is *2 in Formula (3) as a bond bonded to a structural side including Z, a compound having a structure represented by the following Formula (4) is obtained.

In the present invention, a composition for forming a resist underlayer film containing a compound having a structure represented by the following Formula (4) is also preferable.

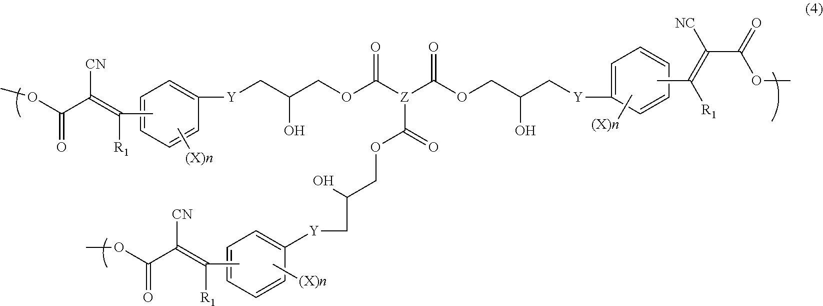

### <<Method for Producing Reaction Product Having Specific Structure>>

The reaction product having a specific structure is obtained by reacting a bifunctional or higher glycidyl ester type epoxy resin with the compound A represented by Formula (A), but the reaction method is not particularly limited, and the reaction product can be produced using a known method. For example, the reaction product can be produced by a method described in Examples described below.

When α-cyano-4 hydroxycinnamic acid is used as the compound A represented by Formula (A) and reacted with terephthalic acid diglycidyl ester, a reaction product having a repeating unit of the following structural formula is obtained.

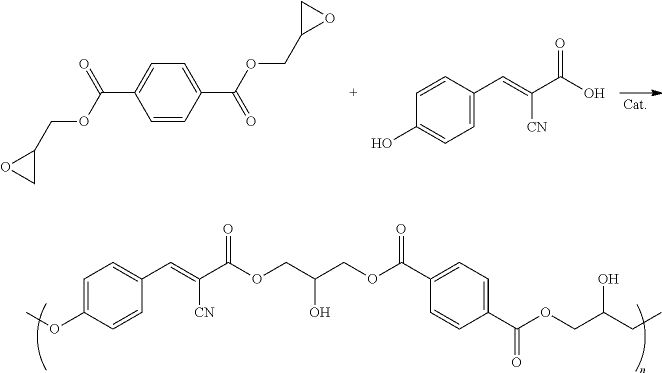

The composition for forming a resist underlayer film of the present invention is a composition for forming a resist underlayer film that can be removed by a chemical liquid for wet etching a copper substrate or the like described below. For this purpose, the composition for forming a resist underlayer film of the present invention can also be used as a composition for application on a substrate containing copper on a surface thereof.

### <Solvent>

The solvent of the composition for forming a resist underlayer film according to the present invention can be used without particular limitation as long as it is a solvent capable of dissolving a reaction product having the specific structure described above, a compound having a structure represented by Formula (1) or Formula (2), or other components described below. In particular, since the composition for forming a resist underlayer film according to the present invention is used in a uniform solution state, it is recommended to use a solvent generally used in a lithography process in combination in consideration of its coating performance.

Examples of the solvent include methyl cellosolve acetate, ethyl cellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, methyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutylpropionate, 3-methyl-3-methoxybutylbutyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. These solvents can be used alone or in combination of two or more thereof.

Propylene glycol monomethyl ether, propylene glycol monomethyl ether acetate, ethyl lactate, butyl lactate, cyclohexanone, and the like are preferable. In particular, propylene glycol monomethyl ether and propylene glycol monomethyl ether acetate are preferable.

The composition for forming a resist underlayer film of the present invention can further contain at least one selected from the group consisting of a crosslinking agent, an acid, and an acid generator, and other components, in addition to the reaction product having a specific structure or the compound having a structure represented by Formula (1) or Formula (2) and the solvent.

### <Crosslinking Agent>

The composition for forming a resist underlayer film of the present invention can contain a crosslinking agent component. Examples of the crosslinking agent include a melamine-based crosslinking agent, a substituted urea-based crosslinking agent, and a polymer-based crosslinking agent thereof. Preferably, the crosslinking agent is a crosslinking agent having at least two crosslinking forming substituents, and is a compound such as methoxymethylated glycoluril (for example, tetramethoxymethyl glycoluril), butoxymethylated glycoluril, methoxymethylated melamine, butoxymethylated melamine, methoxymethylated benzoguanamine, butoxymethylated benzoguanamine, methoxymethylated urea, butoxymethylated urea, or methoxymethylated thiourea. In addition, condensates of these compounds can also be used.

In addition, as the crosslinking agent, a compound containing a crosslinking substituent having an aromatic ring (for example, a benzene ring or a naphthalene ring) in the molecule can be used.

Examples of the compound include a compound having a partial structure of the following Formula (6) and a polymer or oligomer having a repeating unit of the following Formula (7).

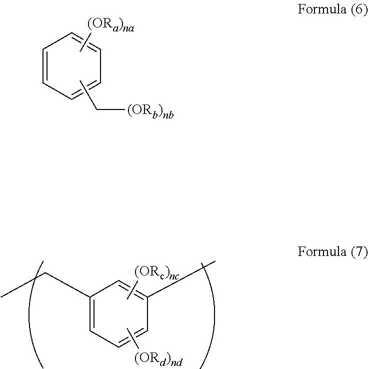

Rₐ, R_{b}, R_{c}, and R_{d} are each a hydrogen atom or an alkyl group having 1 to 10 carbon atoms, and na, nb, nc, and nd each represent an integer from 0 to 3. As the alkyl group, the examples described above can be used.

The compounds, polymers, and oligomers of Formula (6) and Formula (7) are exemplified below.

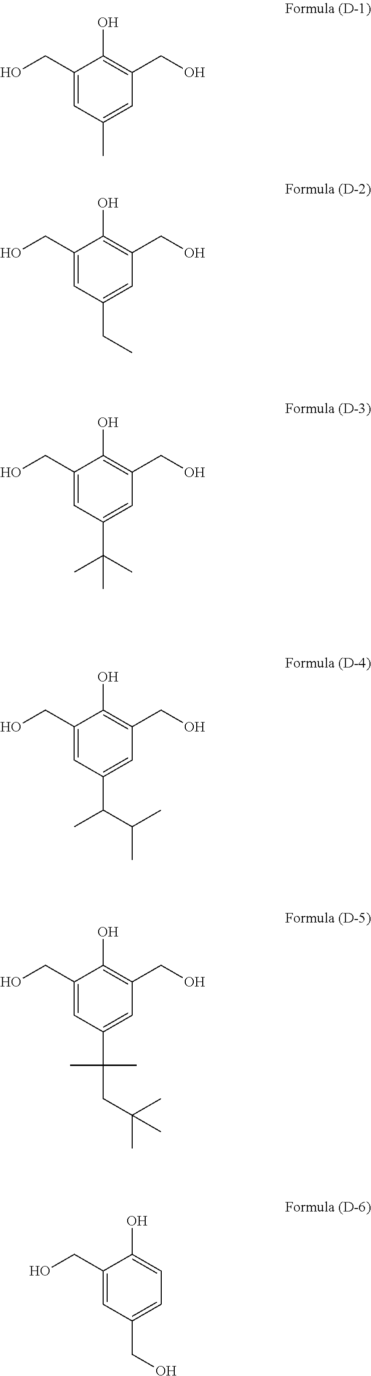 [SMILES: Cc1cc(CO)c(O)c(CO)c1 ; CCc1cc(CO)c(O)c(CO)c1 ; CC(C)(C)c1cc(CO)c(O)c(CO)c1 ; CC(C)C(C)c1cc(CO)c(O)c(CO)c1 ; CC(C)(C)CC(C)(C)c1cc(CO)c(O)c(CO)c1 ; OCc1ccc(O)c(CO)c1]

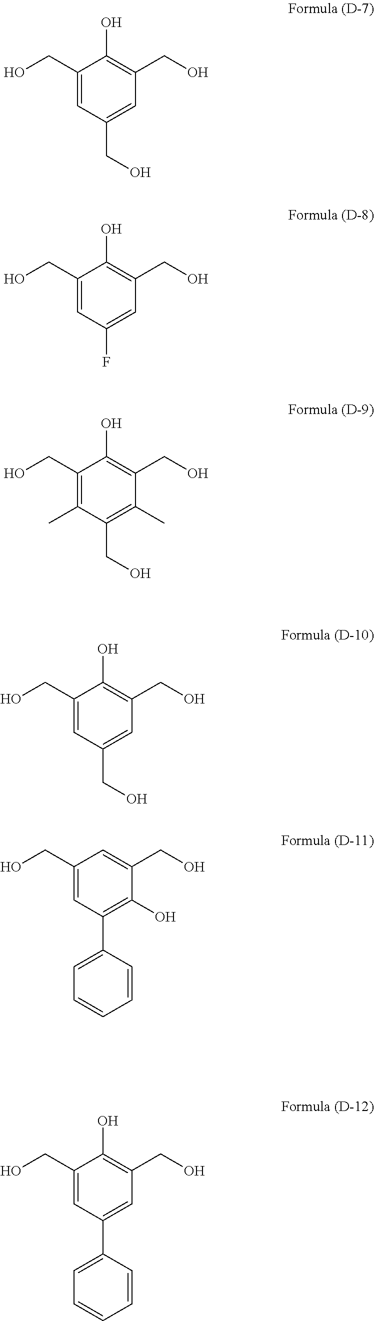 [SMILES: OCc1cc(CO)c(O)c(CO)c1 ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

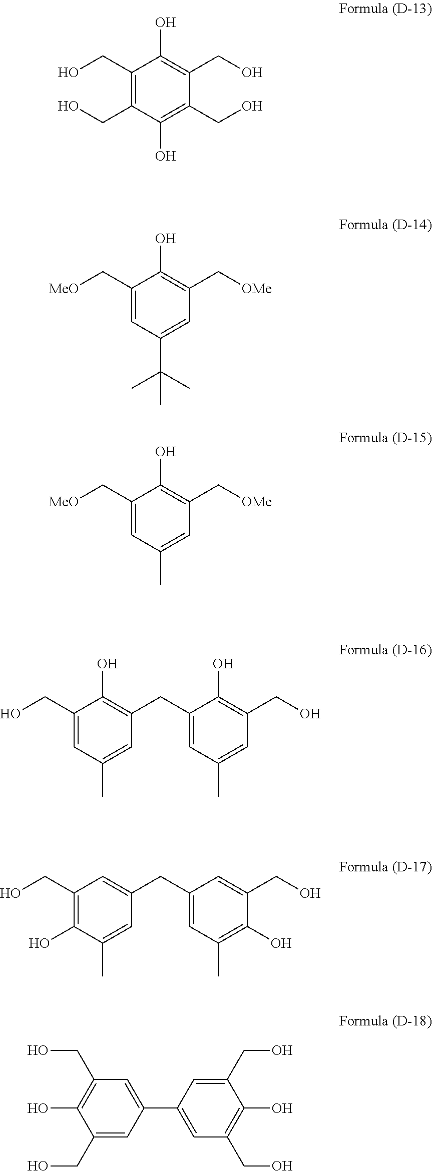

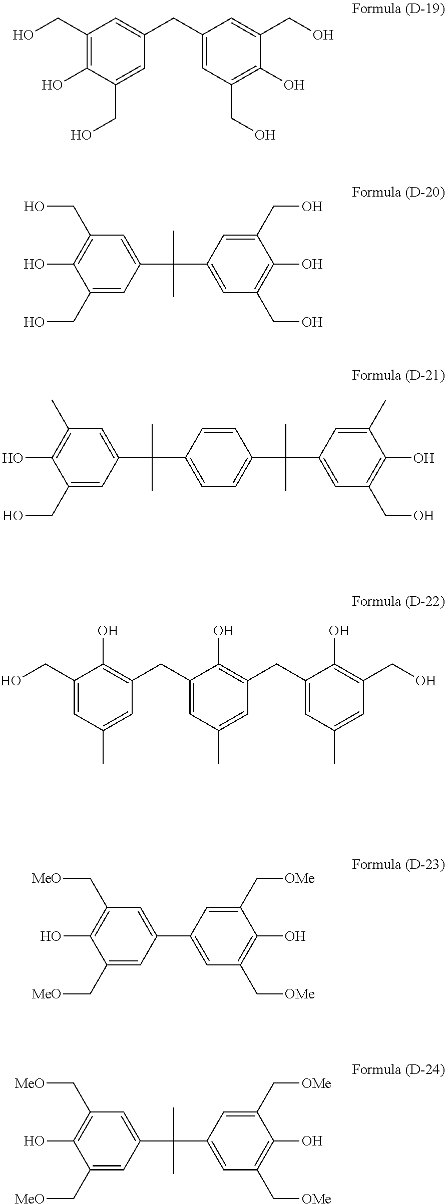 [SMILES: OCc1cc(Cc2cc(CO)c(O)c(CO)c2)cc(CO)c1O ; CC(C)(c1cc(CO)c(O)c(CO)c1)c1cc(CO)c(O)c(CO)c1 ; Cc1cc(C(C)(C)c2ccc(C(C)(C)c3cc(C)c(O)c(CO)c3)cc2)cc(CO)c1O ; Cc1cc(CO)c(O)c(Cc2cc(C)cc(Cc3cc(C)cc(CO)c3O)c2O)c1 ; COCc1cc(-c2cc(COC)c(O)c(COC)c2)cc(COC)c1O ; COCc1cc(C(C)(C)c2cc(COC)c(O)c(COC)c2)cc(COC)c1O]

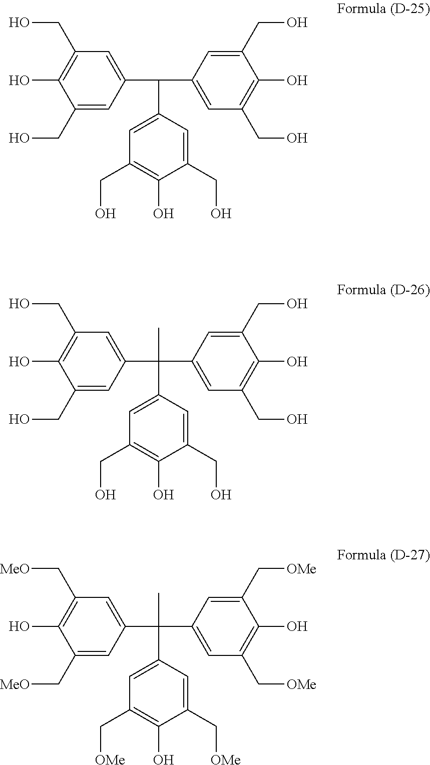 [SMILES: OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The compound can be obtained from products of ASAHI YUKIZAI CORPORATION and Honshu Chemical Industry Co., Ltd. For example, among the crosslinking agents, the compound of Formula (D-24) can be obtained from trade name TM-BIP-A manufactured by ASAHI YUKIZAI CORPORATION.

The amount of the crosslinking agent added varies depending on a coating solvent to be used, a base substrate to be used, a required solution viscosity, a required film shape, and the like, and is 0.001 to 80 mass %, preferably 0.01 to 50 mass %, and more preferably 0.05 to 40 mass %. The crosslinking agent may cause a crosslinking reaction due to self-condensation. However, in a case where a crosslinkable substituent is present in the reaction product of the present invention, the crosslinking agent may cause a crosslinking reaction with the crosslinkable substituent.

<Acid and/or Acid Generator>

The composition for forming a resist underlayer film of the present invention can contain an acid and/or an acid generator.

Examples of the acid include p-toluenesulfonic acid, trifluoromethanesulfonic acid, pyridinium trifluoromethanesulfonic acid, pyridinium p-toluenesulfonic acid, pyridinium phenolsulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

As the acid, only one kind of acid can be used, or two or more kinds of acids can be used in combination. A blending amount is usually 0.0001 to 20 mass %, preferably 0.0005 to 10 mass %, and more preferably 0.01 to 3 mass %, with respect to the total solid content.

Examples of the acid generator include a thermal acid generator and a photoacid generator.

Examples of the thermal acid generator include pyridinium trifluoromethanesulfonic acid, pyridinium p-toluenesulfonic acid, pyridinium phenol sulfonic acid, 2,4,4,6-tetrabromo cyclohexadienone, benzoin tosylate, 2-nitrobenzyl tosylate, and other organic sulfonic acid alkyl esters.

The photoacid generator generates an acid during exposure of the resist. Therefore, the acidity of the underlayer film can be adjusted. The photoacid generator is one method for adjusting the acidity of the underlayer film to the acidity of the upper layer resist. In addition, the pattern shape of the resist formed on the upper layer can be adjusted by adjusting the acidity of the underlayer film.

Examples of the photoacid generator contained in the composition for forming a resist underlayer film of the present invention include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds such as triphenylsulfonium hexafluoroantimonate, triphenylsulfonium nonafluoro-n-butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Specific examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

As the acid generator, only one kind of acid generator can be used, or two or more kinds of acid generators can be used in combination.

In a case where the acid generator is used, a ratio thereof is usually 0.0001 to 20 mass %, preferably 0.0005 to 10 mass %, and more preferably 0.01 to 3 mass %, with respect to 100 parts by mass of the solid content of the composition for forming a resist underlayer film.

### <Other Components>

In the composition for forming a resist underlayer film of the present invention, a surfactant can be blended in order to further improve the coatability for surface unevenness without generating pinholes, striations, and the like. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (manufactured by Tochem Products Co. Ltd., trade name), Megafac F171, F173, R-40, R-40N, and R-40LM (manufactured by DIC Corporation, trade name), Fluorad FC430 and FC431 (manufactured by Sumitomo 3M Limited, trade name), and AsahiGuard AG710 and Surflon 5-382, SC101, SC102, SC103, SC104, SC105, and SC106 (manufactured by AGC Inc., trade name), and organosiloxane polymer KP341 (manufactured by Shin-Etsu Chemical Co., Ltd.).

A blending amount of these surfactants is usually 2.0 mass % or less, and preferably 1.0 mass % or less, with respect to the total solid content of the resist underlayer film material. These surfactants can be used alone or in combination of two or more thereof. When the surfactant is used, a ratio thereof is 0.0001 to 5 parts by mass, 0.001 to 1 part by mass, or 0.01 to 0.5 parts by mass, with respect to 100 parts by mass of the solid content of the composition for forming a resist underlayer film.

A light absorber, a rheology modifier, an adhesion assistant, or the like can be added to the composition for forming a resist underlayer film of the present invention. The rheology modifier is effective in improving fluidity of the composition for forming an underlayer film. The adhesion assistant is effective in improving adhesion between the semiconductor substrate or the resist and the underlayer film.

As the light absorber, commercially available light absorbers described in “Technique and Market of Industrial Pigments” (CMC Publishing Co., Ltd.) or “Dye Handbook” (edited by The Society of Synthetic Organic Chemistry, Japan), such as C.I. Disperse Yellow 1, 3, 4, 5, 7, 8, 13, 23, 31, 49, 50, 51, 54, 60, 64, 66, 68, 79, 82, 88, 90, 93, 102, 114, and 124; C.I. Disperse Orange 1, 5, 13, 25, 29, 30, 31, 44, 57, 72, and 73; C.I. Disperse Red 1, 5, 7, 13, 17, 19, 43, 50, 54, 58, 65, 72, 73, 88, 117, 137, 143, 199, and 210; C.I. Disperse Violet 43; C.I. Disperse Blue 96; C.I. Fluorescent Brightening Agent 112, 135, and 163; C.I. Solvent Orange 2 and 45; C.I. Solvent Red 1, 3, 8, 23, 24, 25, 27, and 49; C.I. Pigment Green 10; and C.I. Pigment Brown 2, can be suitably used. The light absorber is usually blended in a ratio of 10 mass % or less, and preferably 5 mass % or less, with respect to the total solid content of the composition for forming a resist underlayer film.

The rheology modifier is added mainly to improve fluidity of the composition for forming a resist underlayer film, and in particular, to improve thickness uniformity of the resist underlayer film or to enhance filling properties of the composition for forming a resist underlayer film into holes in a baking step.

Specific examples thereof include phthalic acid derivatives such as dimethyl phthalate, diethyl phthalate, diisobutyl phthalate, dihexyl phthalate, and butyl isodecyl phthalate; adipic acid derivatives such as di-n-butyl adipate, diisobutyl adipate, diisooctyl adipate, and octyldecyl adipate; maleic acid derivatives such as di-n-butyl maleate, diethyl maleate, and dinonyl maleate; oleic acid derivatives such as methyl oleate, butyl oleate, and tetrahydrofurfuryl oleate; and stearic acid derivatives such as n-butyl stearate and glyceryl stearate.

These rheology modifiers are usually blended in a ratio of less than 30 mass % with respect to the total solid content of the composition for forming a resist underlayer film.

The adhesion assistant is mainly added to improve adhesion of the composition for forming a resist underlayer film to a substrate or a resist, and in particular, to prevent peeling of the resist in development.

Specific examples thereof include chlorosilanes such as trimethylchlorosilane, dimethylmethylolchlorosilane, methyldiphenylchlorosilane, and chloromethyldimethylchlorosilane; alkoxysilanes such as trimethylmethoxysilane, dimethyldiethoxysilane, methyldimethoxysilane, dimethylmethylolethoxysilane, diphenyldimethoxysilane, and phenyltriethoxysilane; silazanes such as hexamethyldisilazane, N,N′-bis(trimethylsilyl)urea, dimethyltrimethylsilylamine, and trimethylsilylimidazole; silanes such as methyloltrichlorosilane, γ-chloropropyltrimethoxysilane, γ-aminopropyltriethoxysilane, and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea such as 1,1-dimethyl urea or 1,3-dimethyl urea or thiourea compounds.

These adhesion assistants are usually blended in a ratio of less than 5 mass %, and preferably less than 2 mass %, with respect to the total solid content of the composition for forming a resist underlayer film.

A solid content of the composition for forming a resist underlayer film according to the present invention is usually 0.1 to 70 mass %, 0.1 to 60 mass %, 0.1 to 50 mass %, 0.1 to 40 mass %, 0.1 to 30 mass %, 0.1 to 20 mass %, 0.1 to 10 mass %, 0.1 to 5 mass %, 0.1 to 3 mass %, or 0.1 to 2 mass %. The solid content is a content ratio of all components excluding the solvent from the composition for forming a resist underlayer film. A ratio of the reaction product in the solid content is preferably in the order of 1 to 100 mass %, 1 to 99.9 mass %, 50 to 99.9 mass %, 50 to 95 mass %, and 50 to 90 mass %.

One of the indice for evaluating whether the composition for forming a resist underlayer film is in a uniform solution state is to observe permeability through a specific microfilter, and the composition for forming a resist underlayer film according to the present invention permeates through a microfilter having a pore size of 0.1 μm and exhibits a uniform solution state.

Examples of a material of the microfilter include fluorine-based resins such as polytetrafluoroethylene (PTFE) and a tetrafluoroethylene-perfluoroalkyl vinyl ether copolymer (PFA), polyethylene (PE), ultra high molecular weight polyethylene (UPE), polypropylene (PP), polysulfone (PSF), polyether sulfone (PES), and nylon, and a microfilter formed of polytetrafluoroethylene (PTFE) is preferable.

### (Resist Underlayer Film and Method for Manufacturing Semiconductor Device)

Hereinafter, a resist underlayer film and a method for manufacturing a semiconductor device using the composition for forming a resist underlayer film according to the present invention will be described.

First, a substrate used for manufacturing a semiconductor device will be described.

### <Substrate>

In the present invention, a substrate used for manufacturing a semiconductor device includes, for example, a silicon wafer substrate, a silicon/silicon dioxide coating substrate, a silicon nitride substrate, a glass substrate, an ITO substrate, a polyimide substrate, a low dielectric constant material (low-k material) coating substrate, and the like.

Note that, in recent years, in the three-dimensional mounting field of semiconductor manufacturing processes, the FOWLP process has started to be applied for the purpose of high-speed responsiveness and power saving by shortening the wiring length between semiconductor chips. In a redistribution layer (RDL) process of creating a wiring between semiconductor chips, copper (Cu) is used as a wiring member, and it is necessary to apply an anti-reflective film (composition for forming a resist underlayer film) as the copper wiring becomes finer. The composition for forming a resist underlayer film according to the present invention can also be suitably applied onto a substrate containing copper and copper oxide on a surface thereof.

The composition for forming a resist underlayer film of the present invention is applied onto a substrate (for example, a substrate containing copper on a surface thereof) used for manufacturing the semiconductor device described above by an appropriate coating method such as a spinner or a coater, and then baked to form a resist underlayer film.

The baking conditions are appropriately selected from a baking temperature of 80° C. to 400° C. and a baking time of 0.3 to 60 minutes. Preferably, the baking temperature is 150° C. to 350° C. and the baking time is 0.5 to 2 minutes. Here, a thickness of the underlayer film to be formed is, for example, 10 to 1,000 nm, 20 to 500 nm, 30 to 400 nm, or 50 to 300 nm.

In addition, an inorganic resist underlayer film (hard mask) can be formed on the organic resist underlayer film according to the present invention. For example, in addition to the method for forming a silicon-containing resist underlayer film (inorganic resist underlayer film) forming composition described in WO 2009/104552 A1 by spin coating, a Si-based inorganic material film can be formed by a CVD method or the like.

Next, a resist film, for example, a photoresist layer is formed on the resist underlayer film. The photoresist layer can be formed by a well-known method of removing a solvent from a coating film made of the composition for forming a resist underlayer film, that is, by applying a photoresist composition solution onto the underlayer film and baking the photoresist composition. A thickness of the photoresist is, for example, 50 to 10,000 nm or 100 to 2,000 nm.

The photoresist formed on the resist underlayer film is not particularly limited as long as it is sensitive to light used for exposure. Both a negative photoresist and a positive photoresist can be used. Examples of the photoresist include a positive photoresist formed of a novolac resin and 1,2-naphthoquinonediazide sulfonic acid ester, a chemically amplified photoresist formed of a binder having a group degradable by an acid to increase an alkali dissolution rate and a photoacid generator, a chemically amplified photoresist formed of a low molecular weight compound degradable by an acid to increase an alkali dissolution rate of the photoresist, an alkali-soluble binder, and a photoacid generator, and a chemically amplified photoresist formed of a binder having a group degradable by an acid to increase an alkali dissolution rate, a low molecular weight compound degradable by an acid to increase an alkali dissolution rate of the photoresist, and a photoacid generator. Examples thereof include APEX-E (trade name) manufactured by Shipley Company L.L.C, PAR710 (trade name) manufactured by Sumitomo Chemical Co., Ltd., and SEPR430 (trade name) manufactured by Shin-Etsu Chemical Co., Ltd. In addition, examples thereof include a fluorine-containing atomic polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

Next, a resist pattern is formed by irradiation with light or an electron beam and development. First, exposure is performed through a predetermined mask. For the exposure, a near ultraviolet ray, a far ultraviolet ray, an extreme ultraviolet ray (for example, EUV (wavelength 13.5 nm)), or the like is used. Specifically, i-line (wavelength: 365 nm), a KrF excimer laser (wavelength: 248 nm), an ArF excimer laser (wavelength: 193 nm), an F2 excimer laser (wavelength: 157 nm), and the like can be used. Among them, i-line (wavelength: 365 nm) is preferable. After the exposure, post exposure bake can be performed, if necessary. After the exposure, heating is performed under conditions appropriately selected from a heating temperature of 70° C. to 150° C. and a heating time of 0.3 to 10 minutes.

In addition, in the present invention, a resist for electron beam lithography can be used instead of a photoresist. As the electron beam resist, both a negative type and a positive type can be used. Examples of the photoresist include a chemically amplified resist formed of a binder having a group degradable by an acid generator and an acid to change an alkali dissolution rate, a chemically amplified resist formed of a low molecular weight compound degradable by an alkali-soluble binder, an acid generator, and an acid to change an alkali dissolution rate of the resist, a chemically amplified resist formed of a binder having a group degradable by an acid generator and an acid to change an alkali dissolution rate and a low molecular weight compound degradable by an acid to change an alkali dissolution rate of the resist, a non-chemically amplified resist formed of a binder having a group degradable by an electron beam to change an alkali dissolution rate, and a non-chemically amplified resist formed of a binder having a portion cut by an electron beam to change an alkali dissolution rate. Even in a case of using these electron beam resists, a resist pattern can be formed similarly to a case of using a photoresist obtained using an irradiation source as an electron beam.

Next, development is performed with a developer. Therefore, for example, in a case where a positive photoresist is used, the photoresist of the exposed portion is removed, and a photoresist pattern is formed.

Examples of the developer include alkaline aqueous solutions such as aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and amine aqueous solutions such as ethanolamine, propylamine, and ethylenediamine. Furthermore, a surfactant or the like can be added to the developer. The conditions for the development are appropriately selected from a temperature of 5 to 50° C. and a time of 10 to 600 seconds.

In the present invention, after an organic underlayer film (underlayer) is formed on a substrate, an inorganic underlayer film (intermediate layer) is formed thereon, and a photoresist (upper layer) can be further coated thereon. Therefore, even in a case where a pattern width of the photoresist becomes narrower and the photoresist is thinly coated to prevent the pattern from being collapsed, processing of the substrate can be performed by selecting an appropriate etching gas. For example, it is possible to perform processing on the resist underlayer film using, as an etching gas, a fluorine-based gas having a sufficiently high etching rate with respect to a photoresist, to perform processing on the substrate using, as an etching gas, a fluorine-based gas having a sufficiently high etching rate with respect to an inorganic underlayer film, and to perform processing on the substrate using, as an etching gas, an oxygen-based gas having a sufficiently high etching rate with respect to an organic underlayer film.

Then, the inorganic underlayer film is removed using the photoresist pattern formed as described above as a protective film, and then the organic underlayer film is removed using the film including the patterned photoresist and the inorganic underlayer film as a protective film. Finally, the semiconductor substrate is processed using the patterned inorganic underlayer film and organic underlayer film as protective films.

First, the inorganic underlayer film of the portion from which the photoresist is removed is removed by dry etching to expose the semiconductor substrate. In the dry etching of the inorganic underlayer film, gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride and chlorine trifluoride, chlorine, or trichloroborane and dichloroborane can be used. For the dry etching of the inorganic underlayer film, a halogen-based gas is preferably used, and a fluorine-based gas is more preferably used. Examples of the fluorine-based gas include tetrafluoromethane (CF₄), perfluorocyclobutane (C₄F₃), perfluoropropane (C₃F₃), trifluoromethane, and difluoromethane (CH₂F₂).

Thereafter, the organic underlayer film is removed using the film including the patterned photoresist and the inorganic underlayer film as a protective film.

Since the inorganic underlayer film containing many silicon atoms is hardly removed by dry etching using an oxygen-based gas, the organic underlayer film is often removed by dry etching using an oxygen-based gas.

Finally, the semiconductor substrate is processed. The semiconductor substrate is preferably processed by dry etching using a fluorine-based gas.

Examples of the fluorine-based gas include tetrafluoromethane (CF₄), perfluorocyclobutane (C₄F₃), perfluoropropane (C₃F₃), trifluoromethane, and difluoromethane (CH₂F₂).

In addition, an organic anti-reflective film can be formed on the upper layer of the resist underlayer film before the photoresist is formed. An anti-reflective film composition to be used is not particularly limited, and can be arbitrarily selected from those conventionally used in the lithography process, and the anti-reflective film can be formed by a conventionally used method, for example, application with a spinner or a coater and baking.

The resist underlayer film formed of the composition for forming a resist underlayer film may absorb light used in a lithography process depending on a wavelength of the light. In such a case, it is possible to function as an anti-reflective film having an effect of preventing reflected light from the substrate. Furthermore, the underlayer film formed using the composition for forming a resist underlayer film of the present invention can also function as a hard mask. The underlayer film of the present invention can also be used as a layer for preventing an interaction between a substrate and a photoresist, a layer having a function of preventing an adverse effect on a substrate of a material used for a photoresist or a substance generated during exposure to a photoresist, a layer having a function of preventing a diffusion of substances generated from a substrate during heating and baking into an upper layer photoresist, or a barrier layer for reducing a poisoning effect of a photoresist layer by a semiconductor substrate dielectric layer.

In addition, the underlayer film formed of the composition for forming a resist underlayer film is applied onto a substrate in which via holes used in a dual damascene process are formed, and can be used as a filling material capable of filling the holes without gaps. In addition, the underlayer film can also be used as a planarizing material for planarizing a surface of a semiconductor substrate having irregularities.

On the other hand, for the purpose of simplification of a process step, reduction of substrate damage, and cost reduction, a technique by wet etching removal using a chemical liquid is also studied instead of dry etching removal. However, a resist underlayer film formed using the conventional composition for forming a resist underlayer film originally needs to be a cured film having solvent resistance in order to suppress mixing with the resist at the time of resist coating. In addition, at the time of resist patterning, it is required to use a developer in order to resolve the resist, but resistance to the developer is also essential. Therefore, it is difficult for the conventional technique to make the cured film insoluble in the resist solvent or the developer and soluble only in the wet etching solution. However, according to the composition for forming a resist underlayer film of the present invention, it is possible to provide a resist underlayer film capable of being subjected to such wet processing (etching (removal) with a wet etching solution).

The wet etching solution preferably contains, for example, an organic solvent, and may contain an acidic compound or a basic compound.

Examples of the organic solvent include dimethyl sulfoxide, dimethylformamide, dimethylacetamide, N-methylpyrrolidone, N-ethylpyrrolidone, ethylene glycol, propylene glycol, and diethylene glycol dimethyl ether.

Examples of the acidic compound include an inorganic acid and an organic acid, examples of the inorganic acid include hydrochloric acid, sulfuric acid, nitric acid, and phosphoric acid, and examples of the organic acid include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, acetic acid, propionic acid, trifluoroacetic acid, citric acid, benzoic acid, hydroxybenzoic acid, and naphthalenecarboxylic acid.

In addition, examples of the basic compound include an inorganic base and an organic base, and examples of the inorganic base include an alkali metal hydroxide such as sodium hydroxide or potassium hydroxide, a quaternary ammonium hydroxide such as tetramethylammonium hydroxide, tetraethylammonium hydroxide, or choline, and an amine such as ethanolamine, propylamine, diethylaminoethanol, or ethylenediamine.

Furthermore, the wet etching solution can use only one kind of organic solvent, or can use a combination of two or more kinds of organic solvents.

In addition, as the acidic compound or basic compound, only one kind of acidic compound or basic compound can be used, or two or more kinds of acidic compounds or basic compounds can be used in combination.

A blending amount of the acidic compound or the basic compound is 0.01 to 20 wt %, preferably 0.1 to 5 wt %, and particularly preferably 0.2 to 1 wt %, with respect to the wet etching solution. In addition, the wet etching solution is preferably an organic solvent containing a basic compound, and particularly preferably a mixed solution containing dimethyl sulfoxide and tetramethylammonium hydroxide.

Note that, in recent years, a fan-out wafer level package (FOWLP) process has started to be applied in the three-dimensional mounting field of semiconductor manufacturing processes, and a resist underlayer film can be applied in a redistribution layer (RDL) process for forming a copper wiring.

Typical RDL processes are described below, but are not limited thereto. First, a photosensitive insulating film is formed on a semiconductor chip, and then patterning is performed by light irradiation (exposure) and development to open a semiconductor chip electrode portion. Subsequently, a copper seed layer for forming a copper wiring to be a wiring member by a plating process is formed by sputtering. Further, after a resist underlayer film and a photoresist layer are sequentially formed, light irradiation and development are performed to form a pattern on a resist. An unnecessary resist underlayer film is removed by dry etching, and electrolytic copper plating is performed on the copper seed layer between the exposed resist patterns to form a copper wiring to be a first wiring layer. Further, the unnecessary resist, the resist underlayer film, and the copper seed layer are removed by dry etching or wet etching or both. Further, after the formed copper wiring layer is again covered with an insulating film, a copper seed layer, a resist underlayer film, and a resist are formed in this order, and resist patterning, resist underlayer film removal, and copper plating are performed to form a second copper wiring layer. This process is repeated to form a target copper wiring, and then a bump for extracting an electrode is formed.

Since the composition for forming a resist underlayer film according to the present invention can remove the resist underlayer film by wet etching, it can be particularly preferably used as a resist underlayer film in such an RDL process from the viewpoint of simplifying the process step and reducing damage to the processed substrate.

### EXAMPLES

Hereinafter, the content and effect of the present invention will be described in more detail with reference to Examples, but the present invention is not limited thereto.

An apparatus and the like used for measuring the weight average molecular weight of the polymer obtained in the following Synthesis Example are shown.
Apparatus: HLC-8320GPC manufactured by Tosoh Corporation
GPC column: Shodex [registered trademark] Asahipak [registered trademark] (Showa Denko K.K.)
Column temperature: 40° C.
Flow rate: 0.35 mL/min
Eluent: tetrahydrofuran (THF)
Standard sample: polystyrene (Tosoh Corporation)

### Synthesis Example 1

5.00 g of terephthalic acid diglycidyl ester (product name: EX-711, manufactured by Nagase ChemteX Corporation), 3.43 g of α-cyano-4 hydroxycinnamic acid, 0.29 g of tetrabutylphosphonium bromide, and 34.90 g of propylene glycol monomethyl ether were added to a reaction flask, and the mixture was heated and stirred under a nitrogen atmosphere at an internal temperature of 105° C. for 24 hours. The obtained reaction product corresponded to Formula (1-1), and the weight average molecular weight Mw thereof measured in terms of polystyrene by GPC was 2,716.

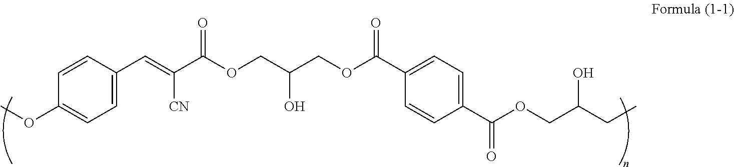

### Synthesis Example 2

5.00 g of terephthalic acid diglycidyl ester (product name: EX-711, manufactured by Nagase ChemteX Corporation), 3.98 g of 2,2-bis(4-hydroxyphenyl)propane, 0.29 g of tetrabutylphosphonium bromide, and 37.08 g of propylene glycol monomethyl ether were added to a reaction flask, and the mixture was heated and stirred under a nitrogen atmosphere at an internal temperature of 105° C. for 24 hours. The obtained reaction product corresponded to Formula (1-2), and the weight average molecular weight Mw thereof measured in terms of polystyrene by GPC was 764.

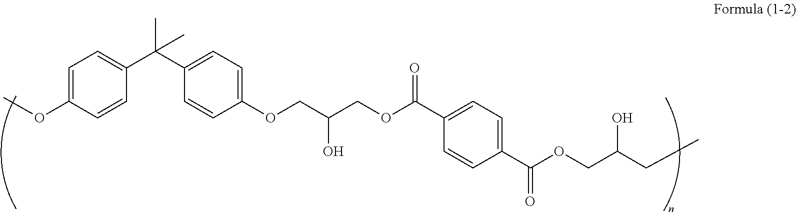

### Synthesis Example 3

5.00 g of resorcinol diglycidyl ether (product name: EX-201-IM, manufactured by Nagase ChemteX Corporation), 4.05 g of α-cyano-4 hydroxycinnamic acid, 0.36 g of tetrabutylphosphonium bromide, and 37.66 g of propylene glycol monomethyl ether were added to a reaction flask, and the mixture was heated and stirred under a nitrogen atmosphere at an internal temperature of 105° C. for 24 hours. The obtained reaction product corresponded to Formula (1-3), and the weight average molecular weight Mw thereof measured in terms of polystyrene by GPC was 1,723.

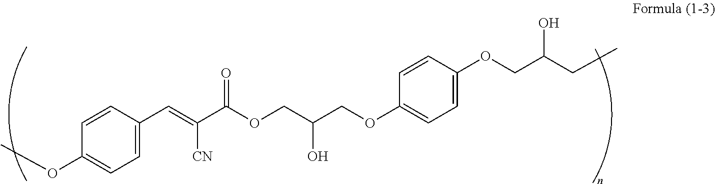

### Synthesis Example 4

5.00 g of resorcinol diglycidyl ether (product name: EX-201-IM, manufactured by Nagase ChemteX Corporation), 4.93 g of 2,2-bis(4-hydroxyphenyl)propane, 0.36 g of tetrabutylphosphonium bromide, and 41.17 g of propylene glycol monomethyl ether were added to a reaction flask, and the mixture was heated and stirred under a nitrogen atmosphere at an internal temperature of 105° C. for 24 hours. The obtained reaction product corresponded to Formula (1-4), and the weight average molecular weight Mw thereof measured in terms of polystyrene by GPC was 5,372.

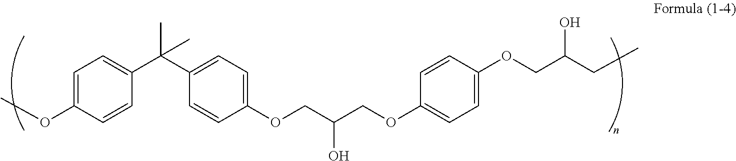

### Synthesis Example 5

15.00 g of a phenol novolac type epoxy resin (product name: DEN, manufactured by The Dow Chemical Company), 10.17 g of 4-hydroxybenzaldehyde, 1.41 g of tetrabutylphosphonium bromide, and 39.87 g of propylene glycol monomethyl ether were added to a reaction flask, and the mixture was heated and refluxed under a nitrogen atmosphere for 24 hours. Subsequently, a solution prepared by dissolving 5.50 g of malononitrile in 34.99 g of propylene glycol monomethyl ether was added to the system, and the mixture was further heated and refluxed for 4 hours. The obtained reaction product corresponded to Formula (1-5), and the weight average molecular weight Mw thereof measured in terms of polystyrene by GPC was 2,200.

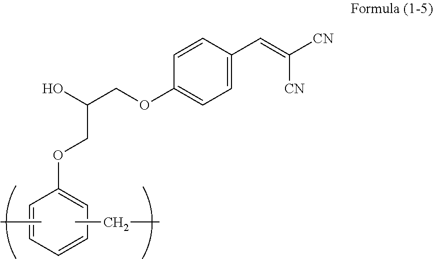

### Example 1

To 0.459 g of a solution of a reaction product corresponding to Formula (1-1) (solid content: 19.7 wt %), 0.027 g of hexamethoxymethylmelamine (trade name: NIKALAC [registered trademark] MW-390, manufactured by Sanwa Chemical Co., Ltd.) as a crosslinking agent, 0.001 g of pyridinium-p-toluenesulfonate as a crosslinking catalyst, 0.002 g of Megaface R-30N (trade name, manufactured by DIC Corporation), 8.52 g of propylene glycol monomethyl ether, and 0.99 g of propylene glycol monomethyl ether acetate were added, thereby preparing a solution of a composition for forming a resist underlayer film.

### Comparative Example 1

To 0.452 g of a solution of a reaction product corresponding to Formula (1-2) (solid content: 20.0 wt %), 0.027 g of hexamethoxymethylmelamine (trade name: NIKALAC [registered trademark] MW-390, manufactured by Sanwa Chemical Co., Ltd.) as a crosslinking agent, 0.001 g of pyridinium-p-toluenesulfonate as a crosslinking catalyst, 0.002 g of Megaface R-30N (trade name, manufactured by DIC Corporation), 8.53 g of propylene glycol monomethyl ether, and 0.99 g of propylene glycol monomethyl ether acetate were added, thereby preparing a solution of a composition for forming a resist underlayer film.

### Comparative Example 2

To 0.459 g of a solution of a reaction product corresponding to Formula (1-3) (solid content: 20.0 wt %), 0.027 g of hexamethoxymethylmelamine (trade name: NIKALAC [registered trademark] MW-390, manufactured by Sanwa Chemical Co., Ltd.) as a crosslinking agent, 0.001 g of pyridinium-p-toluenesulfonate as a crosslinking catalyst, 0.002 g of Megaface R-30N (trade name, manufactured by DIC Corporation), 8.52 g of propylene glycol monomethyl ether, and 0.99 g of propylene glycol monomethyl ether acetate were added, thereby preparing a solution of a composition for forming a resist underlayer film.

### Comparative Example 3

To 0.497 g of a solution of a reaction product corresponding to Formula (1-4) (solid content: 18.2 wt %), 0.027 g of hexamethoxymethylmelamine (trade name: NIKALAC [registered trademark] MW-390, manufactured by Sanwa Chemical Co., Ltd.) as a crosslinking agent, 0.001 g of pyridinium-p-toluenesulfonate as a crosslinking catalyst, 0.002 g of Megaface R-30N (trade name, manufactured by DIC Corporation), 8.49 g of propylene glycol monomethyl ether, and 0.99 g of propylene glycol monomethyl ether acetate were added, thereby preparing a solution of a composition for forming a resist underlayer film.

### Comparative Example 4

To 1.645 g of a solution of a reaction product corresponding to Formula (1-5) (solid content: 28.6 wt %), 0.118 g of tetramethoxymethyl glycoluril (trade name: POWDER LINK [registered trademark] 1174, manufactured by Nippon Scientific Co., Ltd.) as a crosslinking agent, 0.012 g of pyridinium-p-toluenesulfonate as a crosslinking catalyst, 7.521 g of propylene glycol monomethyl ether, and 0.708 g of propylene glycol monomethyl ether acetate were added, thereby preparing a solution of a composition for forming a resist underlayer film.

### <Evaluation of Optical Constant>

For an evaluation of the optical constant, the composition for forming a resist underlayer film for lithography prepared in each of Example 1 and Comparative Examples 1 to 3 was applied onto a silicon wafer with a spin coater so as to have a film thickness of about 50 nm, and baked on a hot plate at 200° C. for 90 seconds. For the obtained resist underlayer film, an n value (refractive index) and a k value (attenuation coefficient) at wavelengths of 193 nm (ArF excimer laser light wavelength), 248 nm (KrF excimer laser light wavelength), and 365 nm (i-line wavelength) were measured using a spectroscopic ellipsometer (VUV-VASE, manufactured by J. A. Woolam). The results are shown in Table 1.

TABLE 1

| | n/k (193 nm) | n/k (248 nm) | n/k (365 nm) |
|---|---|---|---|
| Example 1 | 1.59/0.41 | 1.78/0.24 | 1.81/0.19 |
| Comparative | 1.51/0.62 | 1.88/0.13 | 1.63/0.00 |
| Example 1 | | | |
| Comparative | 1.49/0.41 | 1.78/0.11 | 1.81/0.23 |
| Example 2 | | | |
| Comparative | 1.43/0.72 | 1.90/0.03 | 1.81/0.00 |
| Example 3 | | | |

In Examples 1 and 2, appropriate n values and k values are obtained at 193 nm, 248 nm, and 365 nm. From the above results, the coating film obtained using the composition for forming a resist underlayer film obtained in each of Example 1 and Comparative Example 2 has an anti-reflection function capable of suppressing reflection (standing wave) from the base substrate, which becomes a factor of an undesirable resist pattern, in a lithography process using radiation such as an ArF excimer laser, a KrF excimer laser, or i-line. Therefore, the coating film is useful as a resist underlayer film.

### <Evaluation of Etching Selection Ratio>

For an evaluation of an etching selection ratio, the composition for forming a resist underlayer film for lithography prepared in each of Example 1 and Comparative Example 4 was applied onto a silicon wafer with a spin coater so as to have a film thickness of about 100 nm, and baked on a hot plate at 200° C. for 90 seconds. The obtained coating film was dry-etched with CF₄ gas using a dry etching apparatus (product name: RIE-200NL, manufactured by Samco Inc.) to measure a ratio of the dry etching rate of the resist underlayer film (selection ratio of the dry etching rate). The measurement results of the etching selection ratio are shown in Table 2. It can be said that the higher the etching selection ratio, the higher the dry etching rate.

TABLE 2

| | Etching selection ratio |
|---|---|
| | (case where etching selection ratio of |
| | Comparative Example 4 is set to 1) |
| Example 1 | 1.21 |
| Comparative | 1 |
| Example 4 | |

From the above results, it can be said that the composition for forming a resist underlayer film of Example 1 has a higher etching selection ratio and thus has a higher dry etching rate than the composition for forming a resist underlayer film of Comparative Example 4. That is, it is possible to shorten the etching time during dry etching of the resist underlayer film, and it is possible to suppress an undesirable phenomenon in which the resist film thickness decreases when the resist underlayer film is removed by dry etching. Furthermore, the fact that the dry etching time can be shortened can reduce undesirable etching damage to the base substrate of the resist underlayer film, and thus is particularly useful as the resist underlayer film.

### <Test of Removability in Resist Solvent>

For an evaluation of removability in a resist solvent (organic solvent), the composition for forming a resist underlayer film prepared in each of Example 1 and Comparative Examples 1 to 4 was applied onto a copper substrate having a thickness of 50 nm, and heated at 200° C. for 90 seconds to form a resist underlayer film having a thickness of 20 nm. Next, the copper substrate coated with the composition for forming a resist underlayer film was immersed in propylene glycol monomethyl ether acetate (PGMEA), which is a general resist solvent, at room temperature for 1 minute, and the removability of the coating film after immersion was visually observed. The results are shown in Table 3. Note that, when the coating film was removed, it was determined that the coating film did not have resistance to a resist solvent (organic solvent), and when the coating film was not removed, it was determined that the coating film had resistance.

TABLE 3

| | Removability of coatability in resist solvent |
|---|---|
| | (PGMEA) |
| Example 1 | No peeling |
| Comparative | No peeling |
| Example 1 | |
| Comparative | No peeling |
| Example 2 | |
| Comparative | No peeling |
| Example 3 | |
| Comparative | No peeling |
| Example 4 | |

From the above results, in the composition for forming a resist underlayer film of each of Example 1 and Comparative Examples 1 to 4, the coating film on the copper substrate was not removed (peeled) in PGMEA, and therefore it can be said that the composition has excellent chemical resistance to the resist solvent. That is, the coating film obtained using the composition for forming a resist underlayer film of each of Example 1 and Comparative Examples 1 to 4 can suppress an undesirable peeling phenomenon due to the resist solvent, and thus is useful as a resist underlayer film.

### <Test of Removability in Resist Developer>

For an evaluation of removability in a resist developer (alkaline aqueous solution), the composition for forming a resist underlayer film prepared in each of Example 1 and Comparative Examples 1 to 4 was applied onto a copper substrate having a thickness of 50 nm, and heated at 200° C. for 90 seconds to form a resist underlayer film having a thickness of 20 nm. Next, the copper substrate coated with the composition for forming a resist underlayer film was immersed in 2.38 wt % of a tetramethylammonium hydroxide (tetramethylammonium hydroxide: TMAH) aqueous solution (product name: NMD-3, manufactured by TOKYO OHKA KOGYO CO., LTD.), which is an alkaline aqueous solution, at room temperature for 1 minute, and the removability of the coating film after immersion was visually observed. The results are shown in Table 4. Note that, when the coating film was removed, it was determined that the coating film did not have resistance to a resist developer (alkaline aqueous solution), and when the coating film was not removed, it was determined that the coating film had resistance.

TABLE 4

| | Removability of coating film in resist developer |
|---|---|
| | (2.38 wt % TMAH aqueous solution) |
| Example 1 | No peeling |
| Comparative | No peeling |
| Example 1 | |
| Comparative | No peeling |
| Example 2 | |
| Comparative | No peeling |
| Example 3 | |
| Comparative | No peeling |
| Example 4 | |

From the above results, in the composition for forming a resist underlayer film of each of Example 1 and Comparative Examples 1 to 4, the coating film on the copper substrate was not removed (peeled) in the TMAH aqueous solution, and therefore, it can be said that the composition has excellent chemical resistance to the resist developer (alkaline aqueous solution). That is, the coating film obtained using the composition for forming a resist underlayer film of each of Example 1 and Comparative Examples 1 to 4 is useful as a resist underlayer film that requires a development process with an alkaline aqueous solution because it does not cause the undesirable peeling phenomenon due to the resist developer.

### <Test of Solubility in Wet Etching Chemical Liquid>

For an evaluation of removability in a wet etching chemical liquid (basic organic solvent), the composition for forming a resist underlayer film prepared in each of Example 1 and Comparative Examples 1 to 4 was applied onto a copper substrate having a thickness of 50 nm, and heated at 200° C. for 90 seconds to form a resist underlayer film having a thickness of 20 nm. Next, the copper substrate coated with the composition for forming a resist underlayer film was immersed in a dimethyl sulfoxide solution of 0.5 wt % of tetramethylammonium hydroxide (TMAH), which is a basic organic solvent, at 50° C. for 5 minutes, and the removability of the coating film after immersion was visually observed. The results are shown in Table 5. Note that, when the coating film was removed, it was determined that the coating film had excellent removability (peelability) in a basic organic solvent, and when the coating film was not removed, it was determined that the coating film did not have excellent removability (peelability).

TABLE 5

| | Removability of coating film in |
|---|---|
| | wet etching chemical liquid |
| | (dimethyl sulfoxide solution of 0.5 wt % TMAH ) |
| Example 1 | All peeled |
| Comparative | No peeling |
| Example 1 | |
| Comparative | No peeling |
| Example 2 | |
| Comparative | No peeling |
| Example 3 | |
| Comparative | No peeling |
| Example 4 | |

From the above results, in the case of the composition for forming a resist underlayer film of Example 1, the coating film on the copper substrate had sufficient removability in a wet etching chemical liquid (basic organic solvent) as compared with the composition for forming a resist underlayer film of each of Comparative Examples 1 to 4. That is, since the coating film obtained using the composition for forming a resist underlayer film of Example 1 can exhibit excellent removability (peelability) in a wet etching chemical liquid, the coating film is useful in a semiconductor manufacturing process of removing the resist underlayer film using a wet etching chemical liquid.

### INDUSTRIAL APPLICABILITY

According to the present invention, it is possible to provide a resist underlayer film that exhibits excellent removability and preferably solubility only in a wet etching chemical liquid while mainly exhibiting excellent resistance to a resist solvent, which is an organic solvent, or a resist developer, which is an alkaline aqueous solution.

1. A composition for forming a resist underlayer film for i-line, the composition comprising:
a reaction product of a bifunctional or higher glycidyl ester type epoxy resin and a compound A represented by the following Formula (A); and
a solvent, 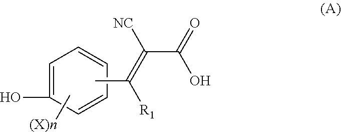
(in Formula (A), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, and n represents an integer from 0 to 4).

2. A composition for forming a resist underlayer film for i-line, the composition comprising a compound having a structure represented by the following Formula (1) or a compound having a structure represented by the following Formula (2), and a solvent, 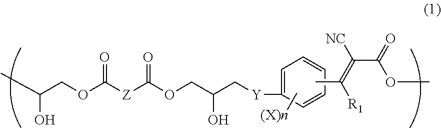
(in Formula (1), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, Z represents an alkylene group having 1 to 6 carbon atoms, a divalent organic group containing a ring selected from the group consisting of an aromatic ring which may have a substituent, an aliphatic ring which may have a substituent, and a heterocyclic ring which may have a substituent, or a divalent organic group containing the ring and an alkylene group having 1 to 6 carbon atoms, and n represents an integer from 0 to 4), 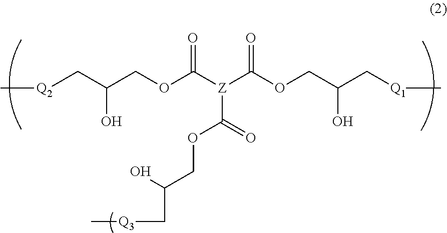
(in Formula (2), Z represents a trivalent organic group containing a ring selected from the group consisting of an aromatic ring which may have a substituent, an aliphatic ring which may have a substituent, and a heterocyclic ring which may have a substituent, or a trivalent organic group containing the ring and an alkylene group having 1 to 6 carbon atoms, and Q₁, Q₂, and Q₃ each independently represent a divalent organic group having a structure represented by the following Formula (3)), 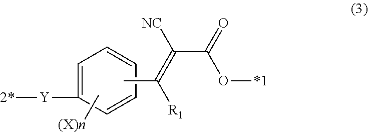
(in Formula (3), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, n represents an integer from 0 to 4, and *1 and *2 each represent a bond).

3. The composition for forming a resist underlayer film for i-line according to claim 1, further comprising at least one selected from the group consisting of a crosslinking agent, an acid, and an acid generator.

4. The composition for forming a resist underlayer film for i-line according to claim 1, wherein the composition is applied onto a substrate containing copper on a surface of the substrate.

5. A resist underlayer film obtained by removing a solvent from a coating film made of the composition for forming a resist underlayer film for i-line according to claim 1.

6. A resist underlayer film obtained from the composition for forming a resist underlayer film for i-line according to claim 1 that is baked, dried, or concentrated.

7. The resist underlayer film according to claim 5, wherein the resist underlayer film is formed on a substrate containing copper on a surface of the substrate.

8. A substrate comprising a copper seed layer, and the resist underlayer film according to claim 5 formed on the copper seed layer, the copper seed layer and the resist underlayer film being formed on a surface of the substrate.

9. A method for manufacturing a substrate including a patterned resist film, the method comprising:
a step of forming a resist underlayer film by applying the composition for forming a resist underlayer film for i-line according to claim 1 onto a substrate containing copper on a surface of the substrate and baking the composition;
a step of forming a resist film by applying a resist onto the resist underlayer film and baking the resist;
a step of exposing the resist underlayer film and a semiconductor substrate coated with the resist; and
a step of developing the resist film after the exposure and performing patterning.

10. A method for manufacturing a semiconductor device, the method comprising:
a step of forming a resist underlayer film from the composition for forming a resist underlayer film for i-line according to claim 1 on a substrate containing copper on a surface of the substrate;
a step of forming a resist film on the resist underlayer film;
a step of forming a resist pattern by irradiating the resist film with light or an electron beam and subsequent development, and then removing the resist underlayer film exposed between the resist patterns;
a step of performing copper plating between the formed resist patterns; and
a step of removing the resist pattern and the resist underlayer film existing under the resist pattern.

11. The method for manufacturing a semiconductor device according to claim 10, wherein at least one of the steps of removing the resist underlayer film is performed by wet processing.

12. A compound (1) having a structure represented by the following Formula (1): 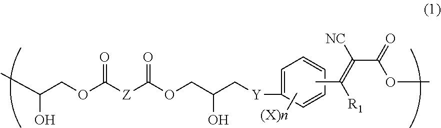
(in Formula (1), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, Z represents an alkylene group having 1 to 6 carbon atoms, a divalent organic group containing a ring selected from the group consisting of an aromatic ring which may have a substituent, an aliphatic ring which may have a substituent, and a heterocyclic ring which may have a substituent, or a divalent organic group containing the ring and an alkylene group having 1 to 6 carbon atoms, and n represents an integer from 0 to 4).

13. A compound (2) having a structure represented by the following Formula (2): 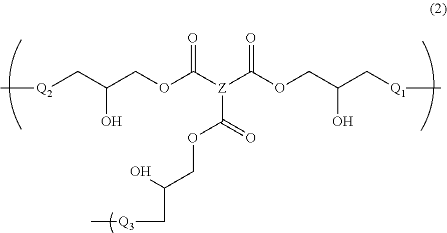
(in Formula (2), Z represents a trivalent organic group containing a ring selected from the group consisting of an aromatic ring which may have a substituent, an aliphatic ring which may have a substituent, and a heterocyclic ring which may have a substituent, or a trivalent organic group containing the ring and an alkylene group having 1 to 6 carbon atoms, and Q₁, Q₂, and Q₃ each independently represent a divalent organic group having a structure represented by the following Formula (3)), 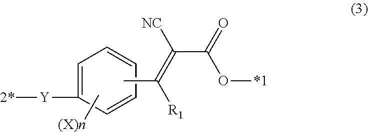
(in Formula (3), R₁ represents a hydrogen atom, an alkyl group having 1 to 10 carbon atoms, or an aryl group having 6 to 40 carbon atoms, X represents an alkyl group having 1 to 10 carbon atoms, a hydroxy group, an alkoxy group having 1 to 10 carbon atoms, an alkoxycarbonyl group having 1 to 10 carbon atoms, a halogen atom, a cyano group, a nitro group, or a combination thereof, —Y— represents —O—, —S—, —SO₂—, —SO—, —COO—, or —NH—, n represents an integer from 0 to 4, and *1 and *2 each represent a bond).

14. The composition for forming a resist underlayer film for i-line according to claim 2, further comprising at least one selected from the group consisting of a crosslinking agent, an acid, and an acid generator.

15. The composition for forming a resist underlayer film for i-line according to claim 2, wherein the composition is applied onto a substrate containing copper on a surface of the substrate.

16. A resist underlayer film obtained by removing a solvent from a coating film made of the composition for forming a resist underlayer film for i-line according to claim 2.

17. A resist underlayer film obtained from the composition for forming a resist underlayer film for i-line according to claim 2 that is baked, dried, or concentrated.

18. A substrate comprising a copper seed layer, and the resist underlayer film according to claim 16 formed on the copper seed layer, the copper seed layer and the resist underlayer film being formed on a surface of the substrate.

19. A method for manufacturing a substrate including a patterned resist film, the method comprising:
a step of forming a resist underlayer film by applying the composition for forming a resist underlayer film for i-line according to claim 2 onto a substrate containing copper on a surface of the substrate and baking the composition;
a step of forming a resist film by applying a resist onto the resist underlayer film and baking the resist;
a step of exposing the resist underlayer film and a semiconductor substrate coated with the resist; and
a step of developing the resist film after the exposure and performing patterning.

20. A method for manufacturing a semiconductor device, the method comprising:
a step of forming a resist underlayer film from the composition for forming a resist underlayer film for i-line according to claim 2 on a substrate containing copper on a surface of the substrate;
a step of forming a resist film on the resist underlayer film;
a step of forming a resist pattern by irradiating the resist film with light or an electron beam and subsequent development, and then removing the resist underlayer film exposed between the resist patterns;
a step of performing copper plating between the formed resist patterns; and
a step of removing the resist pattern and the resist underlayer film existing under the resist pattern.
